(19) United States
(12) Patent Application Publication
(10) Pub. No.: US 2005/0280482 A1
(43) Pub. Date: Dec. 22, 2005

(54) Filter

(75) Inventors: Zhi-Hao Shih, Taipei (TW); Hsueh-Ming Shih, Taipei (TW)

Correspondence Address: BIRCH STEWART KOLASCH & BIRCH, PO BOX 747, FALLS CHURCH, VA, 22040-0747, US

(73) Assignees: Hsueh-Ming SHIH; TAK TECHNOLOGY CO., LTD.

(21) Appl. No.: 11/137,359

(22) Filed: May 26, 2005

Related U.S. Application Data
(63) Continuation-in-part of application No. 10/870,038, filed on Jun. 18, 2004.

(51) Int. Cl. H03H 7/01

(52) U.S. Cl. 333/181

(57) ABSTRACT

The current invention discloses a filter for large current applications. The filter comprises a rectangular metal frame including a first shaft at one side and a parallel second shaft at the other side, a first cylinder including two half cylinders coupled together to sleeve on the first shaft, a second cylinder including two half cylinders coupled together to sleeve on the second shaft, a winding formed by coiling wire around the first and the second cylinders, and a base for supporting the metal frame. The invention can increase winding space due to the provision of separate first and second cylinders. Moreover, a simple winding is effected.

### FIELD OF THE INVENTION

The present invention relates to filters and more particularly to a large current filter.

### BACKGROUND OF THE INVENTION

Filters are widely employed in electrical or electronic devices (e.g., computers, TVs, sound reproducing products, etc.). Filters are responsible for preventing the passage of noise and eliminating EMI (electromagnetic interference). A conventional filter 1 is shown in FIGS. 1 and 2 and comprises a metal frame 10 having a section of n and including a transverse shaft 100, and two half cylinders 11 each including two half circular outer grooves 110, a half circular outer trough 111 provided on a wall separating the grooves 110, a toothed section 112 provided along one half circular end, and a half circular axial channel 113 in which both the half cylinders 11 are adapted to engage around the shaft 100 to form a complete cylinder. The filter 1 further comprises a rectangular base 12 including a central recess 120 for receiving the cylinder, two side cavities 121 formed by four corner posts for snugly receiving the sides of the metal frame 10, four pegs 122 extended downwardly from four bottom corners, and a plurality of peripheral longitudinal tunnels 123 (two are shown in either front or rear side). Either wire 13 may pass one tunnel 123 and exit the other tunnel 123 after winding the groove 110. Also, portions of either wire 13 below the tunnels 123 are secured to the pegs 122.

However, the prior art suffered from several disadvantages. For example, the forming of two windings is difficult and may undesirably consume precious time and labor. Also, the insulating outer shell of the wire 13 is subject to damage in the winding process, resulting in a short circuit. Further, the provision of two grooves 110 can occupy a large space, i.e., less space available for two windings of wire 13 (such as enameled wire). As such, the prior filter 1 is simply suitable for small current applications. As a result, power of the filter 1 is relatively small. This prior design is thus low in industrial applicability. Moreover, the size of the metal frame 10 is somewhat bulky (i.e., large thickness), resulting a limited winding space, small current passage, and high power loss. Hence, a need for improvement exists.

### SUMMARY OF THE INVENTION

It is an object of the present invention to provide a filter particular applicable for large current applications.

It is another object of the present invention to provide a filter having an arrangement of preventing dust from entering.

To achieve the above and other objects, the present invention provides a filter comprising a rectangular metal frame including a first shaft at one side and a parallel second shaft at the other side; a first cylinder including two half cylinders coupled together to sleeve on the first shaft; a second cylinder including two half cylinders coupled together to sleeve on the second shaft; a winding formed by coiling wire around the first and the second cylinders; and a base for supporting the metal frame. The present invention can increase winding space due to the provision of separate first and second cylinders. Moreover, the present invention is particularly suitable for large current applications. Further, the present invention has a simple winding.

The above and other objects, features and advantages of the present invention will become apparent from the following detailed description taken with the accompanying drawings.

### BRIEF DESCRIPTION OF THE DRAWINGS

FIG. 1 is an exploded view of a conventional filter;

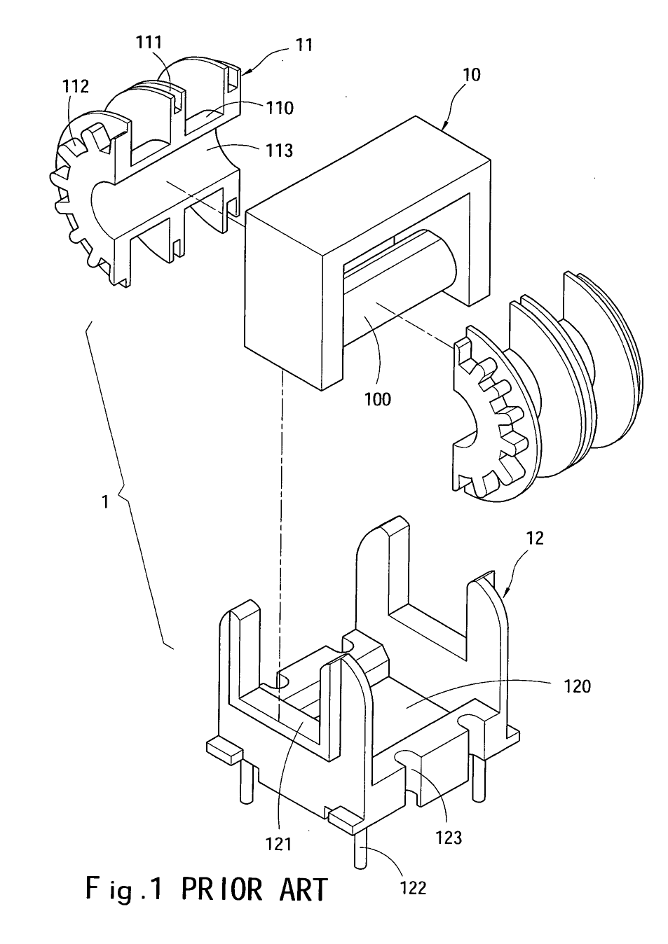

FIG. 2 is a perspective view of the assembled filter shown in FIG. 1;

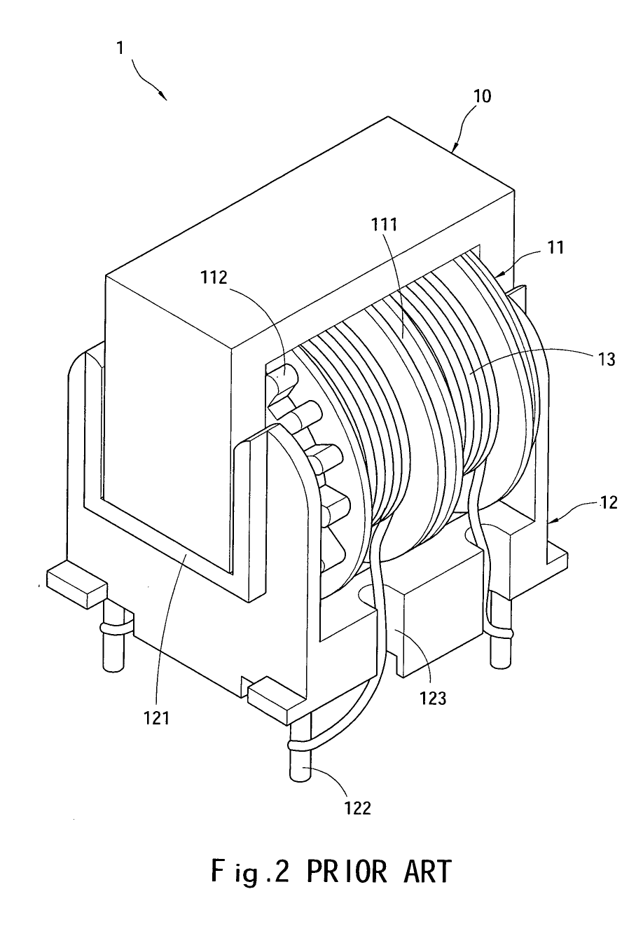

FIG. 3 is an exploded view of a first preferred embodiment of filter according to the invention;

FIG. 4 is a perspective view of the assembled filter shown in FIG. 3;

FIG. 5 is an exploded perspective view of a second preferred embodiment of filter according to the invention;

FIG. 6 is an exploded view of a third preferred embodiment of filter according to the invention;

FIG. 7 is a perspective view of the assembled filter shown in FIG. 6;

FIG. 8 is an exploded view of a fourth preferred embodiment of filter according to the invention; and

FIG. 9 is a perspective view of the assembled filter shown in FIG. 8.

### DETAILED DESCRIPTION OF THE PREFERRED EMBODIMENTS

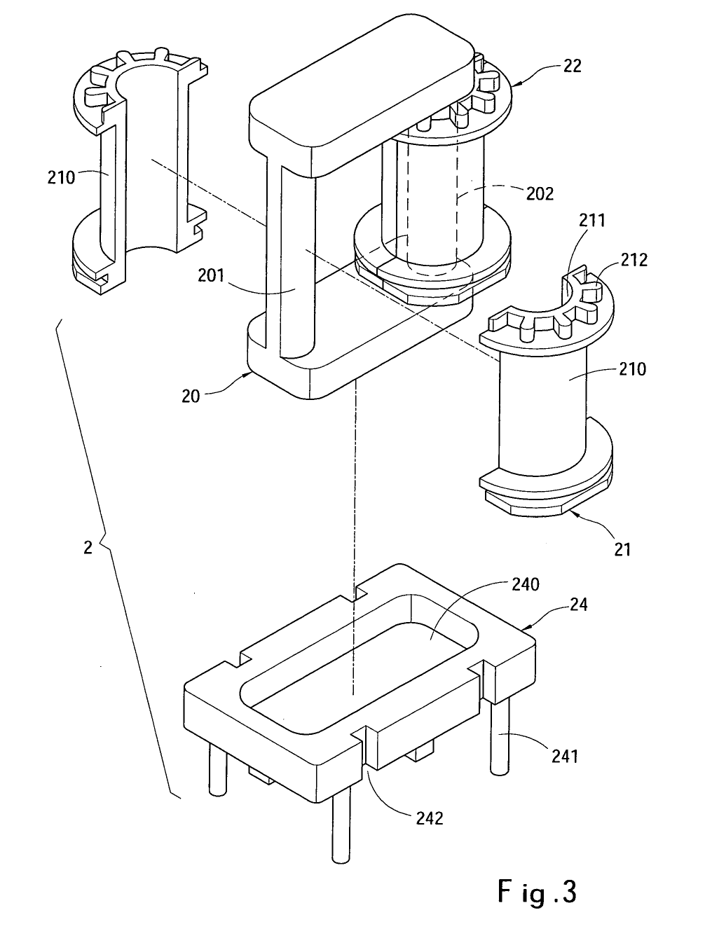

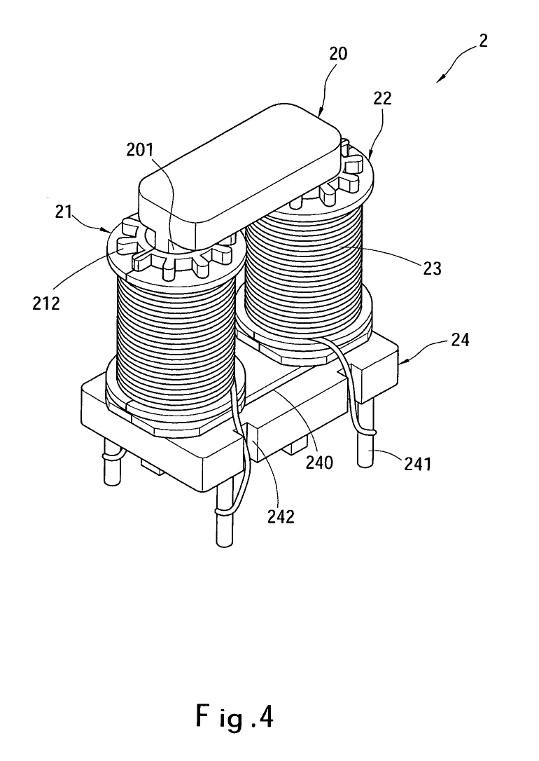

Referring to FIGS. 3 and 4, there is shown a filter 2 constructed in accordance with a first preferred embodiment of the invention comprising a metal frame 20, a first cylinder 21, a second cylinder 22, a winding 23, and a base 24. Each component will be described in detailed below.

The metal frame 20 is implemented as a magnet of high magnetism and is shaped as a rectangle including two parallel first shaft 201 and second shaft 202 at both sides. The thickness of the metal frame 20 is conformed to a combination of the first cylinder 21 and the second cylinder 22. Note that the metal frame 20 of the invention has an increased height and width and has different thickness at different portions such that winding space can be increased to permit a large current to pass and minimize a power loss. The first cylinder 21 is identical to the second cylinder 22. The first cylinder 21 is sleeved on the first shaft 201 and the second cylinder 22 is sleeved on the second shaft 202 respectively. For example, the first cylinder 21 comprises two half cylinders 210 coupled together. The first cylinder 21 comprises an axial channel 211 sleeved on the first shaft 201. The second cylinder 22 also comprises an axial channel 211 sleeved on the second shaft 202. Each of the first cylinder 21 and the second cylinder 22 comprises a top toothed section 212 formed by a gear machine (not shown). The toothed section 212 is adapted to pull and fasten the winding 23. The winding 23 is implemented as a flat wire having copper conductor or a conventional enameled wire. The winding 23 is wound on the first cylinder 21 and the second cylinder 22. The rectangular base 24 includes a top recess 240 for receiving a bottom of the metal frame 20, four pegs 241 extended downwardly from four bottom corners, and two peripheral longitudinal tunnels 242 provided in either front or rear side. The portions of the winding 23 leaving the first cylinder 21 and the second cylinder 22 are adapted to pass the tunnels 242 and be secured to the pegs 241 by, for example, soldering.

In view of the construction of the filter 2, it is seen that the first cylinder 21 and the second cylinder 22 are adapted to sleeve on the first shaft 201 and the second shaft 202 of the metal frame 20 respectively, resulting in an increase of the winding space. In this regard, wire of the winding 23 having a larger section can be used. Accordingly, the filter 2 formed by the winding 23 and other components can be applied to large current applications since the larger section of the winding 23 the larger of electric currents that pass the winding 23. Moreover, separate cylinders (e.g., the first cylinder 21 and the second cylinder 22) can effect a simple, ordered winding, resulting in a decrease of working time and labor. Further, in the case of the winding 23 formed by a flat wire having copper conductor, advantages including being aesthetic, applicable to large current and power applications due to larger section of the wire, reduction of the turns of winding, simple winding procedure, and low power loss can be obtained. Hence, the invention has a highly industrial applicability.

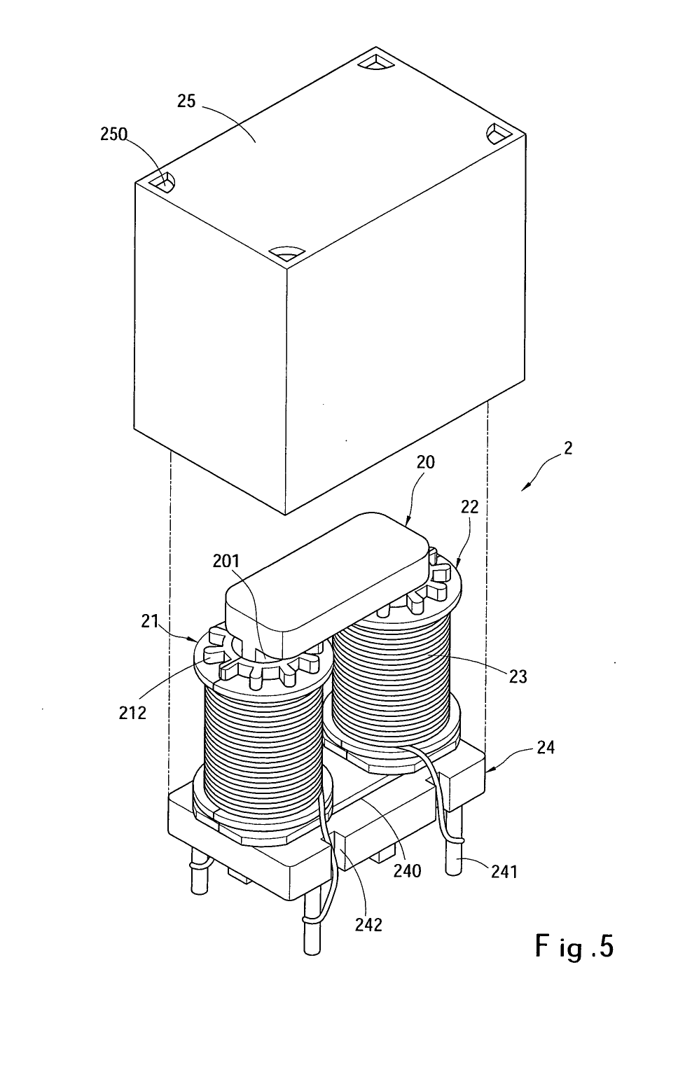

Referring to FIG. 5, there is shown a filter 2 constructed in accordance with a second preferred embodiment of the invention. The characteristics of the second preferred embodiment are detailed below. The filter 2 comprises a metal frame 20, a first cylinder 21, a second cylinder 22, a winding 23, and a base 24. Further, a dust cover 25 formed of acrylic-plastic is adapted to enclose the assembled filter 2. The dust cover 25 can prevent dust and/or other foreign objects from entering the filter 2. This arrangement can prolong the useful life of the filter 2. Also, a plurality of (four are shown) openings 250 are provided on four top corners of the dust cover 25 for ventilation. The second preferred embodiment thus has the capability of being dustproof in addition to be applicable to large current applications and simple winding.

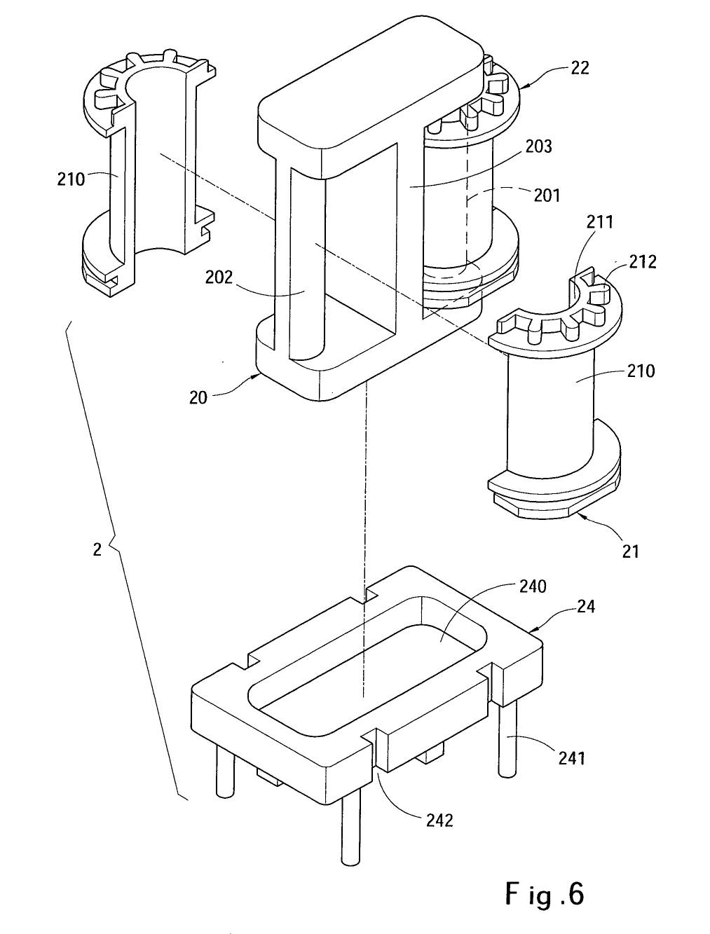

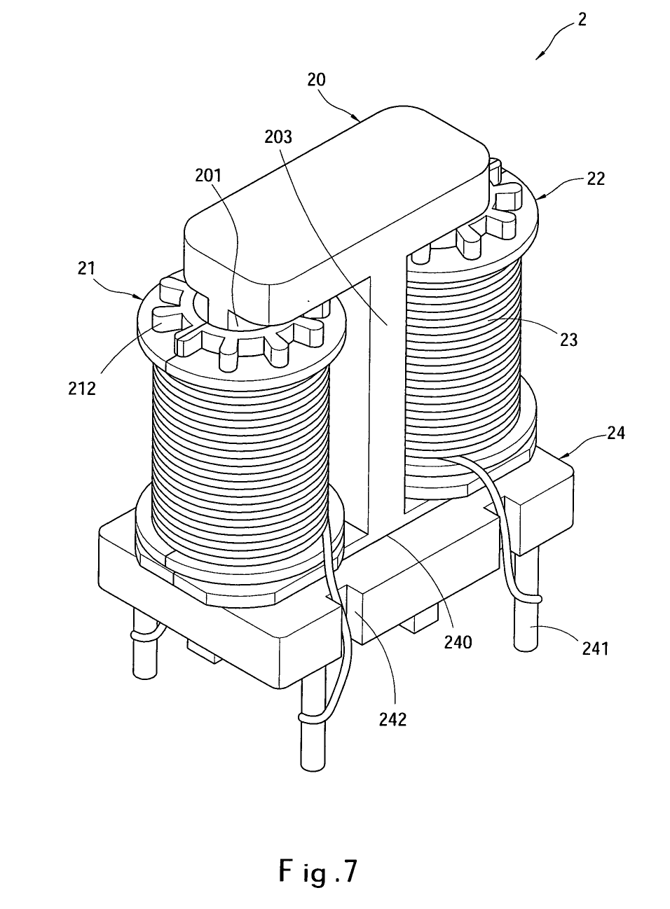

Referring to FIGS. 6 and 7, there is shown a filter 2 constructed in accordance with a third preferred embodiment of the invention. The characteristics of the third preferred embodiment are detailed below. The filter 2 comprises a metal frame 20, a first cylinder 21, a second cylinder 22, a winding 23, and a base 24. A wall 203 is provided between the first shaft 201 and the second shaft 202 of the metal frame 20 for preventing interference therebetween.

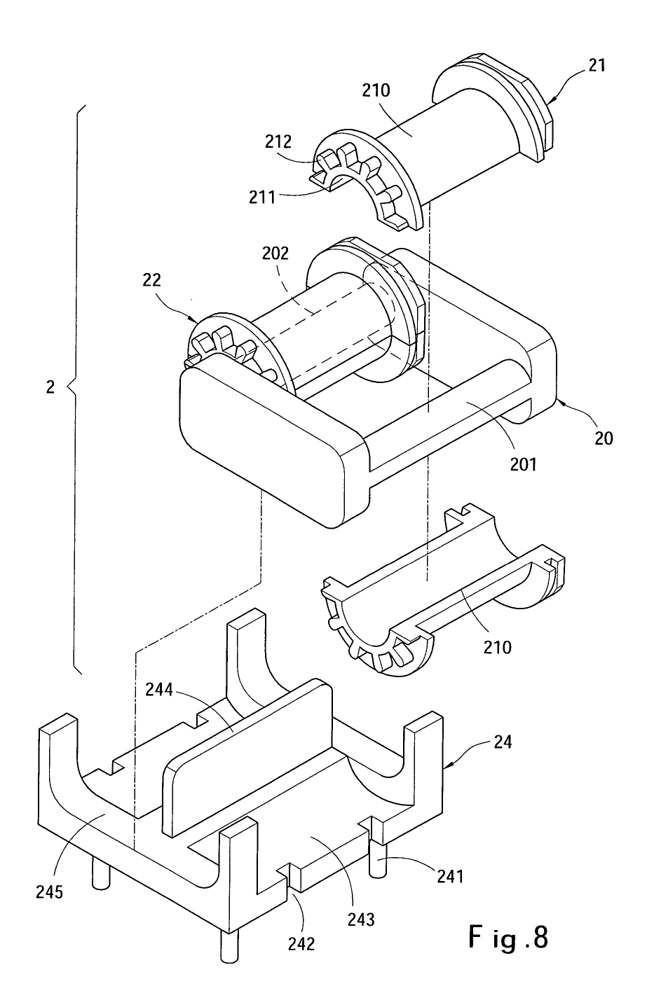

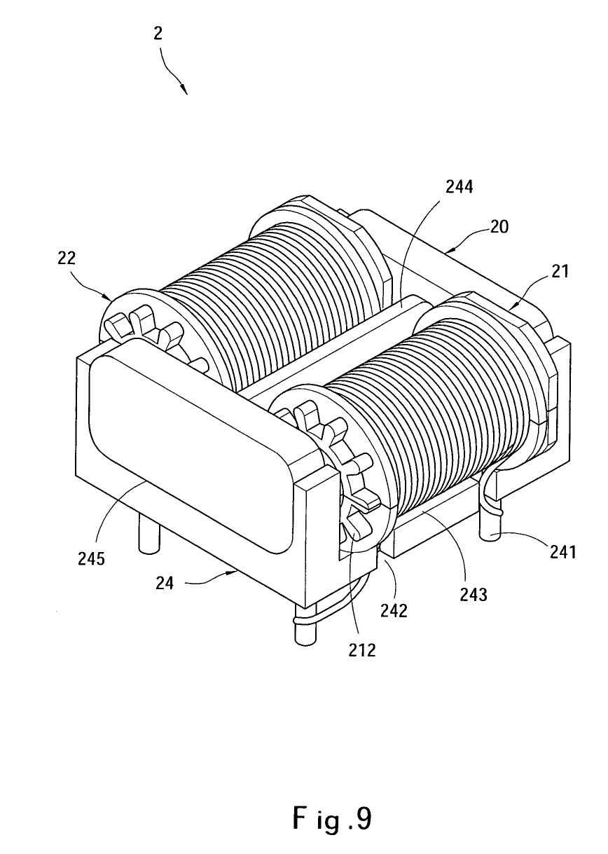

Referring to FIGS. 8 and 9, there is shown a filter 2 constructed in accordance with a fourth preferred embodiment of the invention. The characteristics of the fourth preferred embodiment are detailed below. The filter 2 comprises a metal frame 20, a first cylinder 21, a second cylinder 22, a winding 23, and a base 24. A central transverse wall 244 is formed on the top of the base 24 for forming two side compartments 243 each for receiving the first cylinder 21 or the second cylinder 22. Also, a concave portion 245 is formed on either side of the base 24 so that the metal frame 20 can be snugly seated on the base 24. Further, four pegs 241 are extended downwardly from four bottom corners, and two peripheral longitudinal tunnels 242 are provided in either front or rear side with the portions of the winding 23 leaving the first cylinder 21 and the second cylinder 22 adapted to pass the tunnels 242 and secured to the pegs 241 by, for example, soldering.

While the invention herein disclosed has been described by means of specific embodiments, numerous modifications and variations could be made thereto by those skilled in the art without departing from the scope and spirit of the invention set forth in the claims.

1. A filter for large current applications, comprising:
a rectangular metal frame including a first shaft at one side and a second shaft at the other side which are parallel;
a first cylinder including two half cylinders coupled together to sleeve on the first shaft;
a second cylinder including two half cylinders coupled together to sleeve on the second shaft;
a winding formed by coiling wire around the first and the second cylinders; and
a base for supporting the metal frame.

2. The filter of claim 1, wherein the metal frame has a thickness conformed to a combination of the first and the second cylinders.

3. The filter of claim 1, wherein the winding is a flat wire having copper conductor.

4. The filter of claim 1, wherein the winding is an enameled wire.

5. The filter of claim 1, further comprising a wall disposed between the first and the second shafts.

6. The filter of claim 1, wherein the base comprises a top recess for receiving a bottom of the metal frame.

7. The filter of claim 1, wherein the base further comprises a top, central, transverse wall formed on a top for forming two compartments for receiving the first cylinder and the second cylinder, and a concave portion formed on either side for fastening and supporting the metal frame.

8. The filter of claim 1, wherein the base further comprises a plurality of pegs extended downwardly and a plurality of peripheral longitudinal tunnels so that portions of the winding leaving the first and the second cylinders are adapted to pass the tunnels and be secured to the pegs.

9. The filter of claim 1, further comprising a dust cover adapted to enclose the filter for preventing foreign objects from entering.

10. The filter of claim 9, wherein the dust cover comprises a plurality of openings for ventilation.
